(19) United States
(12) Patent Application Publication
(10) Pub. No.: US 2013/0200498 A1
(43) Pub. Date: Aug. 8, 2013

(54) METHODS AND APPARATUS FOR LITHOGRAPHY USING A RESIST ARRAY

(71) Applicant: Applied Materials, Inc., Santa Clara, CA (US)

(72) Inventor: Shmuel Mangan, Nes-Ziyona (IL)

(73) Assignee: Applied Materials, Inc., Santa Clara, CA (US)

(21) Appl. No.: 13/757,820

(22) Filed: Feb. 3, 2013

Related U.S. Application Data
(60) Provisional application No. 61/594,913, filed on Feb. 3, 2012.

(51) Int. Cl. H01L 21/306; H01L 29/06

(52) U.S. Cl. CPC H01L 21/30604; H01L 29/06
USPC 257/618; 438/694

(57) ABSTRACT

Methods, apparatus, and systems are provided for forming a resist array on a material to be patterned. The resist array may include an arrangement of two different materials that are adapted to react to activation energy differently relative to each other to enable selective removal of only one of the materials (e.g., one is reactive and the other is not reactive; one is slightly reactive and the other is very reactive; one is reactive in one domain and the other in an opposite domain). The first material may be disposed as isolated nodes between the second material. A subset of nodes may be selected from among the nodes in the array and the selected nodes may be exposed to activation energy to activate the nodes and create a mask from the resist array. Numerous additional aspects are disclosed.

This application claims priority to U.S. Provisional Patent Application Ser. No. 61/594,913, filed Feb. 3, 2012, titled “METHODS AND APPARATUS FOR LITHOGRAPHY USING A RESIST ARRAY” which is hereby incorporated by reference herein in its entirety.

### FIELD OF THE INVENTION

The present invention generally relates to electronic semiconductor device manufacturing, and more particularly is directed to patterning process (lithography) methods and apparatus.

### BACKGROUND OF THE INVENTION

Lithography technology has been one of the key enablers and drivers for the semiconductor industry for the past several decades. Improvements in lithography are responsible for roughly half of the improvement in cost per function in integrated circuit (IC) technology. The underlying reason for the driving force in semiconductor technology has been the ability to keep the cost for printing a silicon wafer roughly constant while exponentially reducing the transistor size, therefore dramatically increasing the number of transistors that can be printed per chip at a rate known as Moore's law. ICs have been printed optically with improvements in lens and imaging material technology along with decreases in wavelength used fueling the steady improvement of lithography technology. However, the end of optical lithography technology has been predicted by many and for many years. Many technologies have been proposed and developed to improve on the performance of optical lithography, some succeeded; but the cost and complexity grew rapidly. Alternative techniques were proposed and developed, but to date, none have succeeded. This has been true largely because it has been more economical to advance incremental improvements in the existing optical technology rather than displace it with a new one. What is needed are methods and apparatus for improving the performance (e.g., resolution) of lithography without making the process non-economical or impracticable for production.

### SUMMARY OF THE INVENTION

Inventive methods and apparatus provide for patterning material on a substrate. In some embodiments, the methods may include forming a resist array on the material to be patterned. The resist array may include an arrangement of two different materials that are adapted to react to activation energy differently relative to each other to enable selective removal of only one of the materials (e.g., one is reactive and the other is not reactive; one is slightly reactive and the other is very reactive; one is reactive in one domain or direction and the other in an opposite domain or direction). The first material may be disposed as isolated nodes between the second material. A subset of nodes may be selected from among the nodes in the array and the selected nodes may be exposed to activation energy to activate the nodes and create a mask from the resist array.

In some other embodiments, an electronic device is formed using a resist array. The electronic device includes a structure patterned in a first material using a resist array, the resist array including an arrangement of a second material and a third material. The second and third materials are adapted to react to activation energy differently relative to each other to enable selective removal of one of the second and third materials. The second material is disposed as isolated nodes between the third material, a subset of nodes having been selected from among the nodes in the array, and the selected nodes having been exposed to activation energy to activate the nodes and create a mask from the resist array. The structure may be formed from the mask through an etch process, for example.

Numerous other aspects are provided. Other features and aspects of the present invention will become more fully apparent from the following detailed description, the appended claims and the accompanying drawings.

### BRIEF DESCRIPTION OF THE DRAWINGS

FIG. 1 is a magnified schematic diagram depicting a substrate including a resist array according to embodiments of the present invention.

FIG. 2A is a magnified schematic diagram depicting a substrate including a resist array with nodes selected through exposure to photons (e.g., Extreme Ultraviolet (EUV) exposure) according to embodiments of the present invention.

FIG. 2B is a magnified schematic diagram depicting a substrate including a resist array with nodes selected through exposure to electrons (e.g., Electron Beam Direct Write (EbDW) scanning) according to embodiments of the present invention.

FIG. 3 is a magnified schematic diagram depicting a substrate including a resist array with developed resist nodes according to embodiments of the present invention.

FIG. 4 is a magnified schematic diagram depicting a substrate including etched material using the pattern of developed resist nodes of FIG. 3 according to embodiments of the present invention.

FIG. 5 is a flowchart depicting an example embodiment of methods according to the present invention.

### DETAILED DESCRIPTION

The present invention provides methods and apparatus for positional guided lithography using a resist array to improve the resolution performance of lithography without reducing throughput to impracticable levels. Leading-edge production lithography employs optical projection printing operating at the conventional optical diffraction limit. The image of the master pattern or mask (usually reduced by four or five times) is projected onto a substrate that has been coated with a layer of photosensitive material (e.g., resist). The solubility or selectivity of the resist is changed by exposure to light or other energy so that a pattern emerges upon development (e.g., much like a photograph). The remaining resist pattern is then used for subsequent process steps such as etching or implantation doping.

Conventionally, using lithography involves writing a pattern on a blanket layer of resist (e.g., a thin sheet of resist that covers the entire substrate). Current optical lithography provides resolutions that support 38 nanometer technology. At the point deep ultraviolet (DUV) lithography reaches its resolution limit, however, there appears to be no clear successor patterning lithography technology with better resolution with a practicable throughput rate. Most alternative technologies (e.g., extreme ultraviolet (EUV), direct write, nano-imprint, etc.) are not mature enough to be useable for production. For example, the alternatives to DUV lithography, EUV and E-beam Direct Write (EbDW), in particular may suffer from throughput problems. From a technical point of view, it is possible to pattern features to atomic dimensions with advanced research techniques. However, these nanolithography methods tend to be very slow and are not practicable for production.

Nevertheless, continued design shrink has been achieved by using other non-optical methods, such as double patterning and pitch division through self-aligned double patterning (SADP) methods. The success of these non-optical techniques to provide high quality patterning and to surpass the optical resolution limits opened the way to a new field of molecular self-assembly, and eventually led to the focus on directed self assembly (DSA) through block co-polymer (BCP). A copolymer is a polymer derived from two or more monomeric species, as opposed to a homopolymer where only one monomer is used. BCP is a special type of copolymer that is made of blocks of different polymerized monomers. For example, polystyrene-b-poly(methyl methacrylate) (PS-b-PMMA) is made by first polymerizing styrene, and then subsequently polymerizing methyl methacrylate from the reactive end of the polystyrene chains. The nanoscale structures created from block copolymers may be used for creating devices for use in computer memory, nanoscale-templating and nanoscale separations.

BCPs are interesting because they can “microphase separate” to form periodic nanostructures. Because the blocks are covalently bonded to each other, they do not demix macroscopically. Depending on the relative lengths of each block, several morphologies can be obtained. Sufficiently different block lengths lead to nanometer-sized spheres of one block in a matrix of the second (for example PMMA in polystyrene).

Directed Self-Assembly (DSA) is a patterning technique in which phase-separating materials are designed, such that their phase separation leads to desired nano-structures. Examples of this can include a PS-b-PMMA block co-polymer, which can phase separate into lamella or cylinders depending on their volume fractions. By pre-patterning some guiding patterns on a substrate, the lamella or cylinders may phase-separate into nano structures which are registered to a desired location. In addition to PS-b-PMMA, other systems have been proposed in literature such as polystyrene-b-poly(dimethylsiloxane) (PS-b-PDMS) and even tri-block co-polymers, and di-block co-polymers with mixtures.

The present invention makes one of the phase-separating domains a photo-reactive, e-beam reactive, X-Ray reactive, EUV reactive, or ion implant reactive, or other directed energy source reactive domain. In this case, after the phase-separation and registration of the nano-structure (“resist array”) has been achieved, a subsequent exposure process can be conducted to “select” which resist nodes within the array are selected for pattern transfer.

The DSA solutions may be regarded as a natural successor to SADP, based on the idea of using a large pitch template to create a small pitch pattern using chemical processes. This creates a periodic array of contacts or lines, which will herein be referred to as an array. The advantages of DSA include providing a good solution for reducing pitch for lines and contacts, with good overlay, resolution, line edge roughness (LER), line width roughness (LWR), critical dimension uniformity (CDU) and more. It has been demonstrated that further array density scaling is practical using such techniques. However, as with SADP, DSA uses a complementary method to “cut” or “trim” the periodic pattern of long lines (or dense contacts) at “random access locations” in order to remain with small patterns of arbitrary length (or a sparse array of contacts). A trim process may be accomplished by optical lithography, and this process benefits from the fact that trimming employs a lower resolution than the trimmed array.

The inventors of the present invention have combined the benefits of creating ordered arrays of resist and random access localization in such a way that the writing dose and accuracy can be reduced, thereby providing high throughput and high pattern quality. In place of the blanket sheet of resist used in conventional lithography, the present invention uses a pre-formed array of resist nodes for creating the desired features.

In some embodiments, the array of resist nodes (i.e., resist array) may be formed by DSA methods, for example, to form a two material array (of contacts, lines or other shapes) such that one material is responsive to the writer (e.g., the active material) while the other material is not (e.g., the inactive material). Other methods such as multiple patterning, nano-imprint templates, etc., may also be used to form a resist array. A relatively strong chemically amplified resist (CAR) is used as the responsive or active material, such that only a relatively small dose of energy is employed to activate the resist over a large area. Similarly, the overlay tolerance for dose placement is greatly relaxed by the diffusion effect of the CAR, which spreads the effect to the borders of the resist node. Thus, each discrete resist node in the array essentially has a binary resist state that can be toggled by writing with only a small dose, even if applied inaccurately. Using an EUV scanner at a very low dose, the desired pattern may be written in the array of resist nodes. This enables high throughput with EUV scanners. Likewise, as an alternative embodiment, using an EbDW scanner at a relatively low dose, with relatively low dose accuracy, and at relatively low positional accuracy, enables high throughput patterning of the resist array with such an EbDW scanner.

Embodiments of the present invention provides numerous advantages. The use of a chemical patterning process, such as a DSA process, to create the array of resist nodes provides accurate alignment, controls the CD, the LFR, and the LWR, through chemical processes and provides the desired resolution. This enables breaking of the binding relationships between resist resolution, LER, and resist sensitivity. This opens the way to increasing chemical amplification of the active resist material to allow the use of reduced writing dosage and allow for increased throughput. Embodiments of the present invention bypasses the problem of resist point-spread function (PSF) which limits lithography resolution. Using a lower dose of activation energy is practicable for both exposure with photons, as in EUV, and by electrons, as in EbDW. In both cases, the benefits can be higher throughput and/or lower energy. In addition, the present invention allows the use of EbDW at low beam current, therefore allowing the use of a smaller beam spot size and lower beam voltage. The present invention also allows the use of EbDW on a predefined grid of the size of the printed pitch. This allows use of a significantly reduced number of parallel beams to implement a reasonable throughput rate with EbDW.

Alternatively, the need for a multi-pass scanning pattern is avoided and therefore, throughput is dramatically increased while significantly reducing the amount of information to be transferred to the writing beam. In fact, in some embodiments, only one bit (or less) per resist node may be used to describe the pattern to be written to the array of resist nodes.

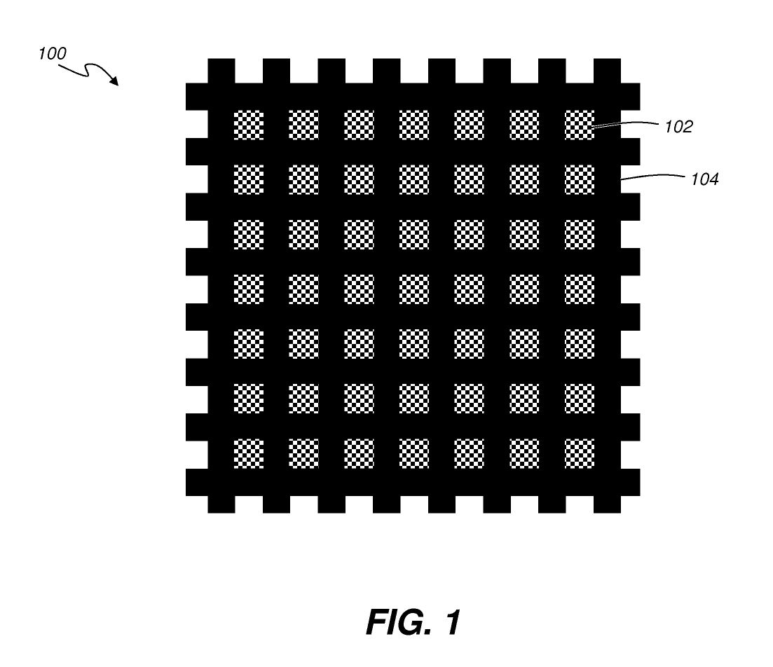

Turning now to the drawings, a substrate undergoing process steps of an example method embodiment of the present invention is depicted in FIGS. 1 through 4. In FIG. 1, a substrate 100 is shown with a pre-formed grid pattern of two materials 102, 104 layered on top of one or more layers of other material(s) (not visible) to be patterned. The first material 102 is a resist, which may be a chemically amplified resist that may be reactive to relatively low dosages of activation energy. The second material 104 is an inactive material that does not react to activation energy. Alternatively, the second material 104 may be a material that is only slightly reactive, oppositely, or inversely reactive to the activation energy, thus creating etch selectivity between the resist islands 102 and the surrounding material 104. In other words, the resist array may include an arrangement of two different materials 102,104 that are adapted to react to activation energy differently relative to each other to enable selective removal of only one of the materials (e.g., one is reactive and the other is not reactive; one is slightly reactive and the other is very reactive; one is reactive in one domain or direction and the other in an opposite domain or direction; etc.).

The grid pattern may be formed using DSA methods know in the art. For example, a chemical epitaxial registration may be implemented, in which a sparse pattern is formed on the substrate 100 which attracts either the first material 102 or the second material 104 during the phase separation event. This makes the “resist array” 102, 104 register on the desired grid. Another method that may be used for registration in some embodiments is a grapho-epitaxy technique in which trenches, slots or holes are pre-patterned into the substrate 100 forcing the phase-separating “resist array” to register within the confines of the pre-pattern. DSA methods allow formation of grid lines and resist nodes having a pitch as small as 15 nm or less. Other patterns of the first and second materials 102, 104 maybe used. For example, hexagonal, pentagonal, octagonal, circular, diamond, compact, elongated, or any other shaped nodes of the first material 102 may be used. Further more, the grid may be an orthogonal grid, a triangular grid, a hexagonal grid, a pentagonal grid, an octagonal grid, or any other shape/type of arrangement of nodes, depending on the design of the pattern desired for substrate 100, design of the pre-pattern formation, and design of the phase-separating materials that make up the resist array.

In some embodiments, the first material 102 may be any of a number of chemically amplified resists such as N-tert-butoxycarbonyl (t-BOC) protected PMMA resist containing photo-acid generators formed in a block-co-polymer with material 104 of poly-styrene. In this example, the first material 102 is the energy reactive domain and the second material 104 is the non-reactive domain.

In other embodiments, the first material 102 may be any of a number of chemically amplified resists such as t-BOC protected PMMA resist formed in a block-co-polymer with material 104 of poly-styrene. After phase separation, a photo-acid generator may be applied to the entire resist array surface, but during energy exposure only the t-BOC protected PMMA domains become “reacted” and developable (e.g., soluble) for pattern transfer.

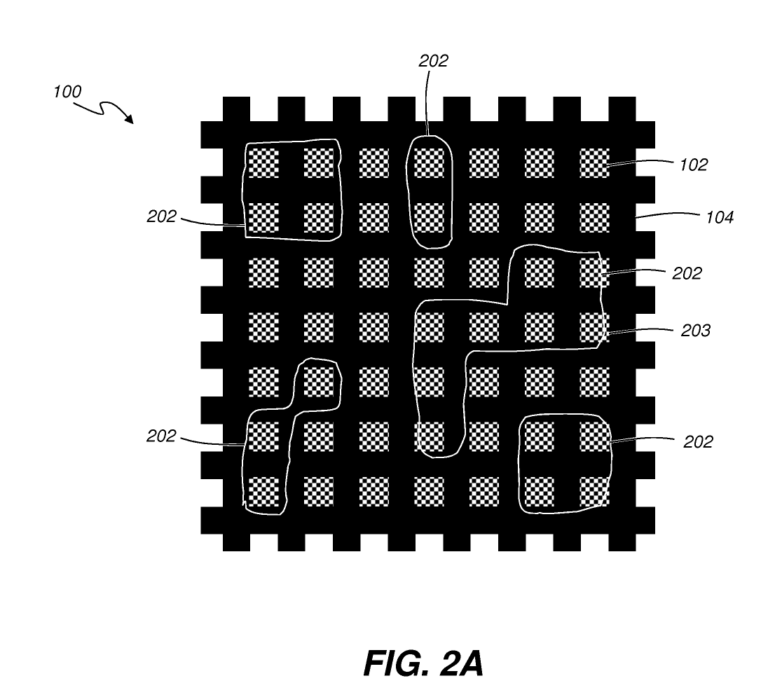

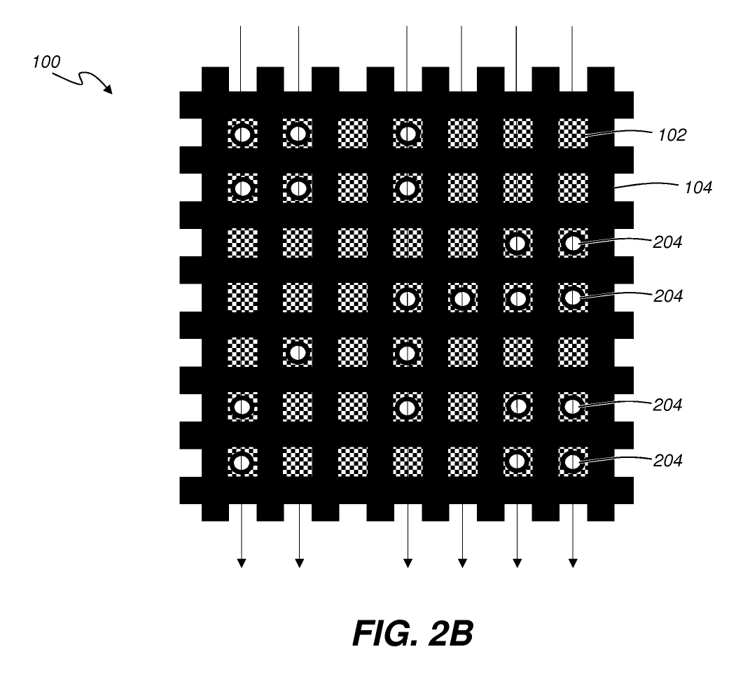

Turning to FIGS. 2A and 2B, two alternative activation methods are illustrated. In FIG. 2A, patterns of selected nodes 202 of the first material 102 are identified for activation with exposure to low dose DUV/EUV energy. Note that the areas of exposure indicated by the white lines generally encircling the selected nodes are not required to include the entire area of the selected nodes 202. In other words, according to embodiments of the present invention, only a portion of the selected node needs to be exposed in order to activate the entire node. Note for example, the node labeled with reference numeral 203 is only partially covered by the area to be exposed with activation energy. For embodiments using EUV exposure to activate the first material, the dosage of EUV may be in the range of approximately 0.011000 mJ/cm² to approximately 1000 mJ/cm², for example. Other dosages may be employed.

Alternatively, in FIG. 2B, individually selected nodes 204 (only four are labeled) are identified for activation with EbDW as the e-beam scans each column of resist nodes of the first material 102. For embodiments using EbDW scanning to activate the first material, the dosage of e-beam energy may be in the range of approximately 10 to approximately 10⁸ electrons per node, for example. Other dosages may be employed.

As indicated by the open circles on each of the selected nodes 204 to be activated, the e-beam, with a beam spot represented by the circles that only covers a portion of each node, is turned on as it rapidly passes over the selected nodes 204 and remains off as it passes over the unselected nodes. Thus, the activation process becomes analogous to a binary process wherein patterns of resist (with the desired resolution, LFR, WFR, and CDU) are merely selected from among the array of resist nodes instead of being entirely defined by the activation energy.

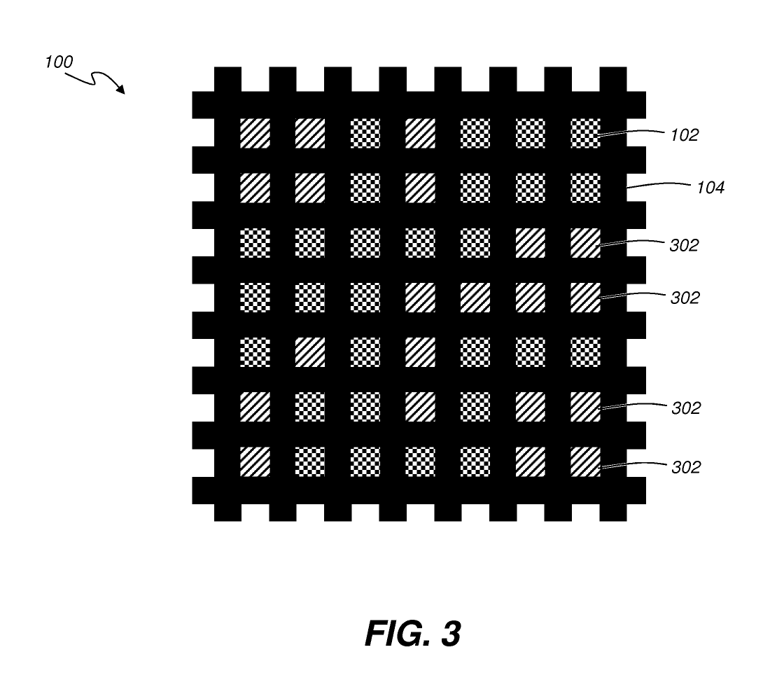

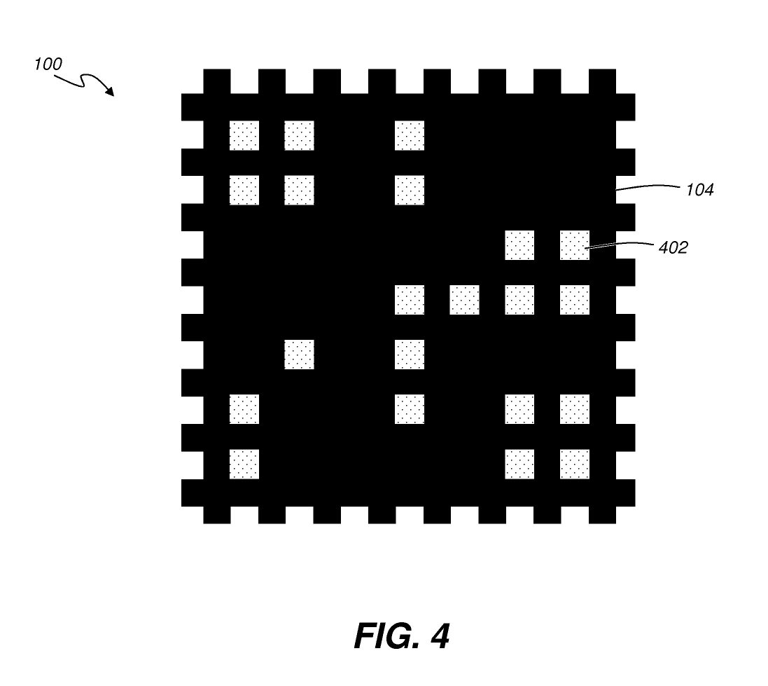

Turning to FIGS. 3 and 4, the exposed (e.g., activated) resist nodes 302 are indicated by the array nodes with a diagonal line pattern and the unexposed resist nodes of the first material 102 are indicated by the array nodes with a checkerboard pattern. The resist nodes 302 then may be developed using a suitable developer solution (e.g., to remove exposed resist node material). In the next step, the substrate 100 is etched and the exposed/developed resist nodes 302 of FIG. 3 become etched patterns (as indicated by the dot pattern) as shown in FIG. 4. For example, at least one material layer of the substrate 100 may be etched through the openings formed by activation/removal of selected nodes 302 as indicated by the dot pattern in FIG. 4.

In some embodiments, different types of materials may be used for the resist. The chosen materials may cause the resist to be a positive or a negative resist. In other words, a positive resist may be used where the selected/exposed nodes become soluble when activated, and once developed, the patterns are then etched; or a negative resist may be used where the selected/exposed nodes become stable (and the others are subsequently washed out during development) and after an etch step, only material under the nodes remains.

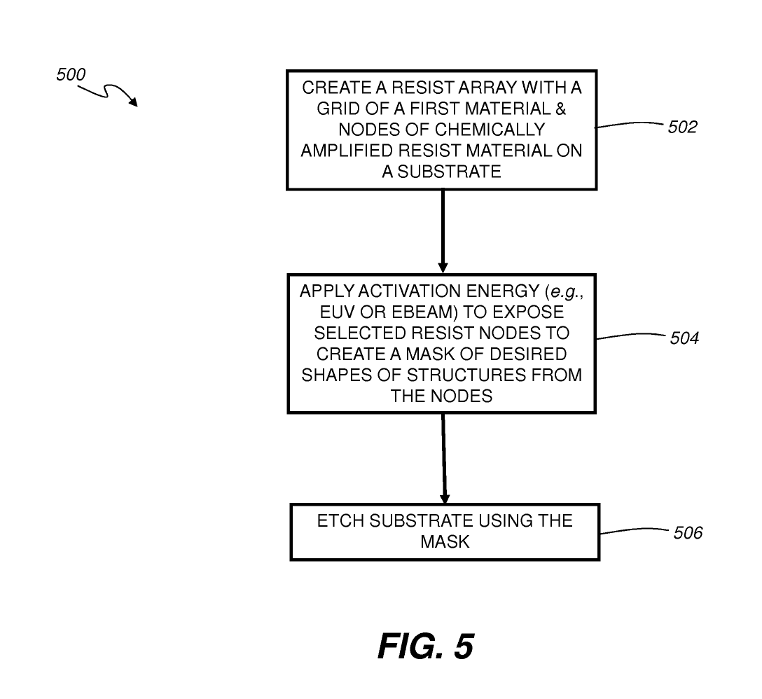

Turing to FIG. 5, a flowchart depicting an example embodiment of a method 500 according to the present invention is depicted. In Step 502, a resist array is created on a substrate over a layer or layers of material(s) to be etched. The layers under the resist array may include one or more of metal layers, silicon, hardmask layers, dielectric layers, organic layers or polymers, and/or the like. The resist array includes a pattern of evenly spaced chemically amplified resist nodes that are reactive to relatively low dosages of activation energy and an intersecting, evenly spaced grid line pattern of inactive material that does not react to activation energy. The nodes fill the spaces between the gridlines. Thus, the nodes are isolated from each other by the gridlines. The grid and node patterns may be formed using DSA methods, for example.

In alternative embodiments, an SADP process may be employed to create a dense array of holes in a first hard mask and a resist blanket may be applied to fill all of the holes. (If a positive resist is used, only those holes that are desired to remain open will be exposed to activation energy and if a negative resist is used, only the holes that are desired to remain closed will be exposed to activation energy.) Once the pattern is developed, the substrate is etched to pattern a second hard mask under the array.

In Step 504, low dose activation energy is applied to individually selected resist nodes to expose these nodes. For example, EUV exposure may be used. Alternatively, EbDW energy may be employed. In some embodiments, other energies and/or resist materials may be used. The selected resist nodes collectively form a pattern that represents the shape of the desired structure to be formed in the layer below the array. Any number of shapes may be created from the nodes including contact/via pads or holes, conductor lines, cut lines, device shapes, etc.

In Step 506, following development of the activated nodes in a suitable developer, the substrate is etched and the resist node pattern is transferred to the underlying material. In some alternative embodiments, multiple array layers may be stacked with a known offset equal to the width of the gridlines to allow more complex or contiguous patterns to be transferred to the underlying materials.

Accordingly, while the present invention has been disclosed in connection with the example embodiments thereof, it should be understood that other embodiments may fall within the spirit and scope of the invention, as defined by the following claims.

The invention claimed is:

1. A method for patterning material on a substrate, the method comprising:
forming a resist array on the material to be patterned, the resist array including an arrangement of a first material and a second material, the first material being disposed as isolated nodes between the second material, wherein the first and second materials are adapted to react to activation energy differently relative to each other to enable selective removal of one of the first and second materials;
selecting a subset of nodes from among the nodes in the array; and
exposing the selected nodes to activation energy to activate the nodes and create a mask from the resist array.

2. The method of claim 1 further comprising etching the material to be patterned using the mask created from the resist array.

3. The method of claim 1 wherein one of the first and second materials is a chemically amplified resist.

4. The method of claim 1 wherein one of the first and second materials is a non-chemically amplified resist.

5. The method of claim 1 wherein one of the first and second materials is a resist, and wherein a chemical amplifier is added to the resist after a phase separation occurs.

6. The method of claim 1 wherein one of the first and second materials is converted into an energy reactable material after a phase separation.

7. The method of claim 1 wherein the selected subset of nodes forms a pattern to be transferred into the material to be patterned.

8. The method of claim 1 wherein the activation energy is in the form of extreme ultra-violet (EUV) light and is applied using an EUV exposure process.

9. The method of claim 1 wherein the activation energy is in the form of an electron beam and is applied using an e-beam direct write (EbDW) process.

10. The method of claim 1 wherein the first material is a chemically amplified resist, wherein the activation energy is in the form of extreme ultra-violet (EUV) light and is applied using a low dose EUV exposure process.

11. The method of claim 1 wherein the first material is a chemically amplified resist, wherein the activation energy is in the form of an electron beam and is applied using a low dose EbDW process.

12. The method of claim 1 wherein the selected subset of nodes forms a pattern in the shape of an arrangement of contact layouts to be transferred into the material to be patterned.

13. The method of claim 1 wherein the selected subset of nodes forms a pattern in the shape of an arrangement of cut lines to be transferred into the material to be patterned.

14. The method of claim 1 wherein the selected subset of nodes forms a pattern in the shape of an arrangement of conductor lines to be transferred into the material to be patterned.

15. The method of claim 1 wherein the resist array is formed in at least one of an orthogonal grid, a rectangular grid, a triangular grid, a hexagonal grid, and an octagonal grid.

16. An electronic device formed using a resist array, the electronic device comprising:
a structure patterned in a first material using a resist array, the resist array including an arrangement of a second material and a third material, wherein the second and third materials are adapted to react to activation energy differently relative to each other to enable selective removal of one of the second and third materials, the second material being disposed as isolated nodes between the third material, a subset of nodes having been selected from among the nodes in the array, and the selected nodes having been exposed to activation energy to activate the nodes and create a mask from the resist array.

17. The electronic device of claim 12 wherein the structure was formed by etching using the mask formed from the resist array.

18. The electronic device of claim 16 wherein the second material is a chemically amplified resist.

19. The electronic device of claim 16 wherein the selected subset of nodes forms a pattern to be transferred into the first material to be patterned.

20. The electronic device of claim 16 wherein the activation energy is in the form of extreme ultra-violet (EUV) light and is applied using an EUV exposure process.

21. The electronic device of claim 16 wherein the activation energy is in the form of an electron beam and is applied using an e-beam direct write (EbDW) process.

22. The electronic device of claim 16 wherein the second material is a chemically amplified resist, wherein the activation energy is in the form of extreme ultra-violet (EUV) light and is applied using a low dose EUV exposure process.

23. The electronic device of claim 16 wherein the second material is a chemically amplified resist, wherein the activation energy is in the form of an electron beam and is applied using a low dose EbDW process.

24. The electronic device of claim 16 wherein the selected subset of nodes forms a pattern in the shape of an arrangement of contact layouts to be transferred into the material to be patterned.

25. The electronic device of claim 16 wherein the selected subset of nodes forms a pattern in the shape of an arrangement of cut lines to be transferred into the material to be patterned.

26. The electronic device of claim 16 wherein the selected subset of nodes forms a pattern in the shape of an arrangement of conductor lines to be transferred into the material to be patterned.
